(19) United States
(12) Patent Application Publication
(10) Pub. No.: US 2005/0164425 A1
(43) Pub. Date: Jul. 28, 2005

(54) Optoelectronic component

(76) Inventors: Markus Tuomikoski, Oulu (FI); Ghassan E. Jabbour, Tucson, AZ (US)

Correspondence Address: YOUNG & THOMPSON, 745 SOUTH 23RD STREET, 2ND FLOOR, ARLINGTON, VA, 22202, US

(21) Appl. No.: 10/762,493

(22) Filed: Jan. 23, 2004

(51) Int. Cl. B32B 3/00; B32B 15/04; H01L 51/40; B32B 7/00; B32B 15/00

(52) U.S. Cl. 438/99; 428/457; 428/209

(57) ABSTRACT

An optoelectronic component includes layers which comprise at least two electrode layers for electric coupling and at least one organic optoelectronically active layers each of the latter layers being placed between at least one pair of electrode layers. In fabrication of the component, at least one organic optoelectronically active layer is formed by transferring a liquid-phase organic optoelectronically active material to a layer of the component from a rotating roll having a direct contact with the layer moving along with rotation of the rotating roll.

### FIELD

The invention relates to an optoelectronic component and a method of fabricating the same.

### BACKGROUND

Organic materials can be used in many optoelectronic applications, such as in electroluminescent devices and solar cells (SCs), mainly due to their simplicity of fabrication, excellent performance characteristics, and mechanical properties. Organic electroluminescent components are typically based on the layered structure of at least one active layer between two electrode layers. Various organic materials are optoelectronically active such that they can be used either to emit or to detect electromagnetic radiation. For example, organic optoelectronically active materials which can be used in the manufacture of Organic Light-Emitting Devices (OLED) include polymers and molecules where the structure of molecular orbitals enables excitation of electrons to a higher excited state, which is thereafter discharged in the form of electromagnetic radiation. In absorbing devices, electromagnetic radiation generates an electric current in a circuit coupled to the electrodes of the device.

Currently, the processing and fabrication of organic-based optoelectronics are carried using traditional techniques, for example, spin coating, dip coating, and vacuum thermal deposition. Screen printing has also been used. In the spin coating, a substrate is rotated so that a centrifugal force spreads the organic optoelectronically active material throughout the surface of the substrate. In the dip coating, a substrate is dipped in to the organic optoelectronically active material to cover the substrate. In the screen printing method a substrate is placed under the screen and the liquid-phase organic optoelectronically active material is placed on the screen. A blade is pulled across the screen for pushing the organic optoelectronically active material through the open holes of the mesh of the screen onto the surface of the substrate. After forming at least one layer, the organic optoelectronically active material is hardened in all these methods.

However, the techniques used in the prior art have several disadvantages, including the geometry of substrates, which is limited. Moreover, the prior art methods, such as vacuum deposition, spin and dip coating waste a lot of organic optoelectronically active material and they are too time consuming particularly for mass production.

### BRIEF DESCRIPTION OF THE INVENTION

An object of the invention is to provide an improved fabrication method and component. According to an aspect of the invention, there is provided a method for fabricating an optoelectronic component including layers, the layers comprising at least two electrode layers for electric coupling and at least one organic optoelectronically active layer, each of the at least one organic optoelectronically active layer being placed between at least one pair of electrode layers. The method comprises forming at least one organic optoelectronically active layer by transferring liquid-phase organic optoelectronically active material onto a surface of a layer of the component from a rotating roll having a direct contact with the surface of the layer moving along with rotation of the rotating roll.

According to an aspect of the invention, there is provided a method for fabricating at least one optoelectronic component, each component including layers, the layers comprising at least two electrode layers for electric coupling and at least one organic optoelectronically active layer, each of the at least one organic optoelectronically active layer being placed between a pair of electrode layers. The method comprises running a continuous substrate layer through a roll-to-roll process using rotating rolls, depositing other layers of the at least one component on the substrate layer; and forming, according to a gravure coating method, at least one organic optoelectronically active layer in the roll-to-roll process by transferring liquid-phase organic optoelectronically active material onto a surface of a layer from a rotating roll having a direct contact with the surface of the layer.

According to another aspect of the invention, there is provided an optoelectronic component including layers, the layers comprising at least two electrode layers for electric coupling and at least one organic optoelectronically active layer, each of the at least one organic optoelectronically active layer being placed between at least one pair of electrode layers, and the at least one organic optoelectronically active layer of the optoelectronic component being formed by a transfer of a liquid-phase organic optoelectronically active material to a surface of a layer of the component from a rotating roll having a direct contact with the surface of the layer moving along with rotation of the rotating roll.

According to an aspect of the invention, there is provided an optoelectronic component including layers, the layers comprising at least two electrode layers for electric coupling and at least one organic optoelectronically active layer, each of the at least one organic optoelectronically active layer being placed between at least one pair of electrode layers, and the at least one organic optoelectronically active layer of the optoelectronic component being formed using a gravure coating method with transfer of a liquid-phase organic optoelectronically active material onto a surface of a layer of the component from a rotating roll having a direct contact with the surface of the layer in a roll-to-roll process where a continuous substrate layer is run through the process using rotating rolls.

Preferred embodiments of the invention are described in the dependent claims.

The present solution provides several advantages. Fabricating components with a rotating roll having a direct contact with the surface on to which the liquid-phase organic optoelectronically active material is transferred avoids problems with the geometry of a substrate, saves organic optoelectronically active material and is fast. Additionally, the present solution is cost-effective, enabling high volume end products.

### LIST OF DRAWINGS

In the following, the invention will be described in greater detail with reference to the preferred embodiments and the accompanying drawings, in which

FIG. 1 shows fabrication of an optoelectronic component;

FIG. 2A shows fabrication of an optoelectronic component;

FIG. 2B shows droplets between electrodes;

FIG. 3 shows fabrication of an optoelectronic component;

FIG. 4 shows roll-to-roll fabrication of an optoelectronic component having several fabrication units;

FIG. 5 shows a layered structure of an optoelectronic component;

FIG. 6 shows a layered structure of an optoelectronic component;

FIG. 7 shows a multilayer optoelectronic component;

FIG. 8 shows an array of optoelectronic components;

FIG. 9 shows a matrix of optoelectronic components;

FIG. 10 shows encapsulation;

FIG. 11 shows a flow chart of a fabrication method; and

FIG. 12 shows a flow chart of a fabrication method.

### DESCRIPTION OF EMBODIMENTS

The present solution is especially suitable for fabrication of optoelectronic components including at least one component having an organic optoelectronically active material between at least one pair of electrodes.

OLEDs have attracted a lot of attention, mainly due to their low operating voltage and power consumption, large viewing angle, high brightness, very thin structure, mechanical flexibility, light weight and a visible full-color range. Moreover, the fabrication of the OLEDs using a gravure method is simple and economic.

Most of the materials used in the OLEDs are amorphous and can thereby be deposited on any flat substrate which may be rigid or flexible. It is also common for the OLED processing that there is no need for lattice-match between a substrate and an optically active layer due to the amorphous nature of organic materials. Thus, nearly all types of materials with various shapes can be used as a substrate. High surface quality is still needed.

Organic light emitting devices are electroluminescence devices. This means that the generation of light results in a radiative decay of excited states formed by injected excess charge carriers. The operation can thus be considered to comprise the following four processes: charge carrier injection, charge carrier transport, electron-hole interaction (formation of excitons) and radiative decay of excitons. Depending on the nature of recombination, maximum internal quantum efficiency can range from a few percentages to 100%, depending on the ratio between decaying processes, i.e. radiative or non-radiative processes.

The present invention utilizes a gravure printing principle. A printing means has defined figures in the form of grooves which can be formed, for example, by etching or engraving. The printing means can be a plate, a cylinder or a roll which may be of metal. The grooves may be organised in a shape of a desired pattern on the printing surface. An engraved roll can be used in printing. Otherwise, the plate can then be rotated on a roll or an engraved cylinder can be placed on the roll. The printing surface can be covered with a liquid-phase printing material to transfer the pattern to an object to be printed.

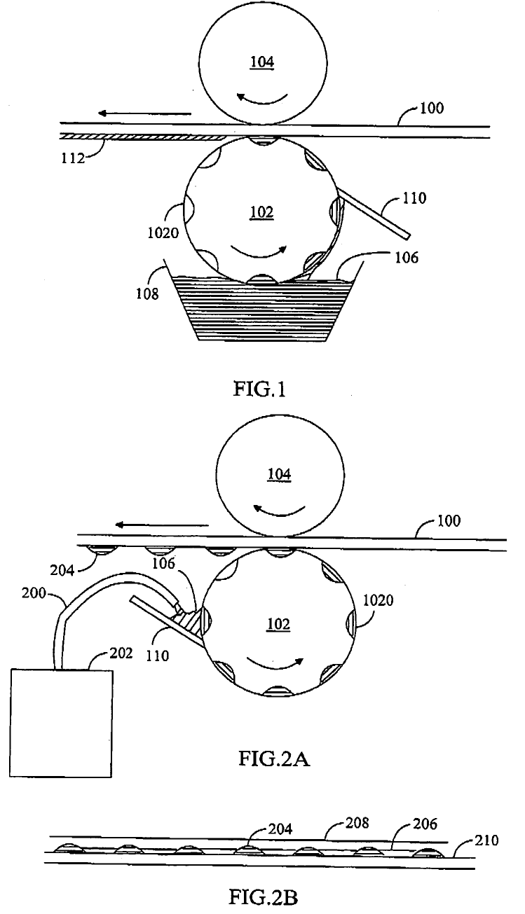

With reference to FIG. 1, examine an example of a gravure coating method. A rigid or flexible substrate 100, which may be made of plastic, glass and plastic laminate, plastic and glass laminate, glass, paper, textile or metal, runs through two rolls 102, 104. Typically, the substrate is flexible and it may be rolled. The substrate 100 may constitute a layer in a component having a layered structure. The roll 102 has cells 1020 to which a liquid-phase component material 106 is transferred when the surface of the roll 102 is dipped into a pot 108 containing the liquid-phase component material 106. The cells can be grooves in the roll 102. The liquid-phase component material may be an organic optoelectronically active material, polymer, metal oxide or metal ink. A doctor blade 110 can be used to remove excess liquid-phase component material on the roll 102. The roll 104 may guide the substrate 100 and the roll 102 into a direct contact with each other for transferring the liquid-phase component material 106 onto a surface of a layer of the component being prepared in the process. In a direct contact, the roll 102 physically touches the substrate 100. The roll 104 may enforce compression between the rolls 102, 104 such that the roll 102 is pressed against the printable surface on the substrate 100. The layer of the component on to which the liquid-phase component material 106 is transferred may be the substrate 100 or a layer processed on the substrate 100 beforehand. The transfer may be carried out by running a continuous substrate through a roll-to-roll process using rotating rolls 102, 104. The viscosity and the surface tension of the liquid-phase component material 106 can be controlled such that the liquid phase component material droplets transferred from the separate cells 1020 join together to form a uniform layer 112 on the layer on which they are transferred. The lower the viscosity and the surface tension, the more easily the liquid-phase component material 106 spreads and forms a uniform layer. The shorter the distance between the cells 1020, the higher also the tendency to form a uniform layer.

Direct gravure coating can be used to form thin, particularly organic layers of the order of tens of nanometers to a few micrometers or even up to hundreds of micrometers in thickness. The viscosity of the liquid-phase component material may vary within a range of below 0.05 Pas to 0.2 Pas, where Pas=Ns/m². The quality of complete layers can be controlled, for example, with the printing speed, and the angle and the force of the doctor blade with respect to the roll 102, etc. With the gravure coating method, a huge number of components can be made with the same roll and a process speed can be more than hundreds of meters per minute. One of the advantages in the transfer of liquid-phase material from a rotating roll to a layer of the component is that it enables high speed fabrication in a low temperature process.

FIG. 2A shows a principle similar to that in FIG. 1 with some modifications. The viscosity and the surface tension of the liquid-phase component material 106 may be controlled such that the liquid-phase component material droplets 204 transferred from the separate cells 1020 may remain separate on the layer on which it is transferred. In this way, each component may have a size of a droplet which may vary, for example in a range from hundreds of nanometers up to millimetres or even more. Another modification compared to FIG. 1 is that the liquid-phase component material 106 may be fed onto a doctor blade 110 via a pipe 200 from a container 202 filled with the liquid-phase component material 106. When the doctor blade 110 wipes up the roll 102, it also fills the cells 1020 of the roll 102 with the liquid-phase component material 106.

FIG. 2B shows droplets between electrodes. An isolating layer 206 may be deposited between the droplets 204 in order to isolate the electrodes 208, 210 from each other.

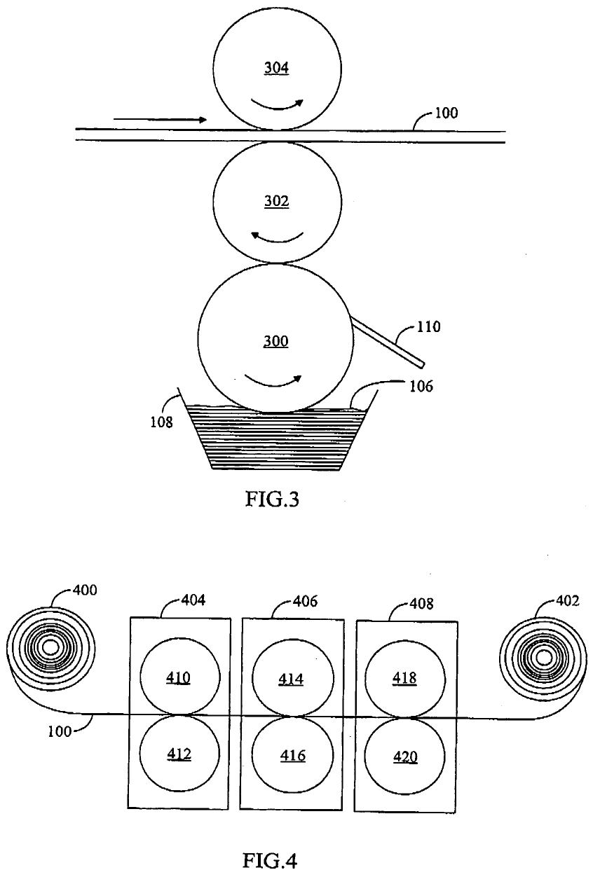

FIG. 3 illustrates another example of a gravure coating method. The transfer of the liquid-phase component material 106 may also be performed indirectly; the covering process can then be considered similar to an offset-gravure or a flexo-gravure. In this embodiment a first roll 300 has the first contact with the liquid-phase component material 106, during which the liquid-phase component material 106 can be spread to the first roll 300 in a manner similar to that in FIG. 1. The spreading may, however, be performed also as in FIG. 2A. The first roll 300 then transfers the liquid-phase component material 106 to a second roll 302, which may be made of a hard (i.e. metal) or soft material (i.e. polymer). The liquid-phase component material 106 can then be transferred from the second roll 302 having a direct contact with the layer to the layer of the component. A roll 304 can be used to enforce compression between the rolls 302 and 304 such that the roll 302 is pressed against the printable surface on the substrate 100.

FIG. 4 illustrates roll-to-roll fabrication. A substrate 100 may be a continuous sheet wound on rolls 400, 402 at both ends of the process. The continuous substrate may be up to many kilometres or even longer in length, the shorter lengths, however, being apparently possible. The substrate may also be up to meters wide. The first roll 400 of the substrate is continually rotated for unwinding the substrate 100 to the process having, for example, three fabrication units 404 to 408. The fabrication units 404 to 408 have pressing rolls 410 to 420 which may be similar to those presented in FIGS. 1 to 3. The fabrication unit 404 transfers the liquid-phase component material from a roll 412 to a component layer of the substrate 100 made beforehand. The substrate 100 then proceeds to the fabrication unit 406 which also transfers of the liquid-phase component material from a roll 416 to a component layer made before the process in the fabrication unit 406. In a similar manner, the fabrication unit 408 transfers of the liquid-phase component material from a roll 420 to a component layer made before the process in the fabrication unit 408. At the end of the process, the substrate is rolled up on the roll 402. The coating process of FIG. 4 with three fabrication units 404 to 408 can produce three layers of the component consecutively. However, the process may have at least one fabrication unit for forming at least one layer of the component in general. If more layers are needed, the substrate 100 with completed layers can be fed to the process repeatedly for forming a desired number of layers. Usually the layers are deposited one upon another.

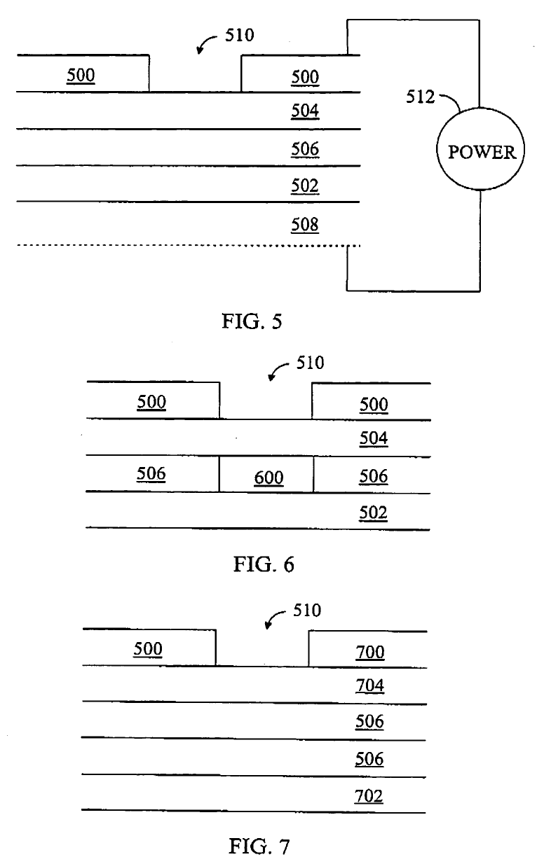

FIG. 5 shows an example of a layered element fabricated using the process described in FIGS. 1 to 4. The element may be a single operational component of its own, or a part of an operational component, such as a pixel in an array, in a matrix structure or in a multilayer structure. The element in FIG. 5 includes four layers 500 to 506, but in general the number of layers may be larger or smaller. The component comprises a pair of electrode layers 500, 502 between which a layer 504 of optoelectronically active material is deposited using the gravure coating method. Additionally, although not necessarily, a structure 506 of at least one operational layer may also be processed between the electrodes 500, 502. The operational layer may be used for increasing the hole and the electron transportation which, in turn, increase the quantum efficiency and improve the luminance of the OLED component.

The layers 500 to 506 may be deposited on a separate substrate 508 which may, for example, be a plastic film. However, the separate substrate 508 is not necessarily needed if, for example, the lowest electrode layer 502 is used as a substrate. In such a case, the electrode layer 502 may be a metal sheet or any other electrically conductive sheet. The thickness of the substrate may vary from a thin film having a thickness of a fraction of a millimetre to a much thicker plate.

All layers except the substrate layer (layer 508 or layer 502) may be formed by transferring a liquid-phase component material to a surface of a layer of the component from a rotating roll having a direct contact with the surface of the layer moving along with the rotation of the rotating roll. This may be carried out by running a continuous substrate through a roll-to-roll process using rotating rolls. For example, the anode electrode layer 502 may be formed by transferring a liquid-phase electrode material to a surface of the substrate 508 from a rotating roll having a direct contact with the substrate moving along with the rotation of the rotating roll.

The liquid-phase electrode layer 502 is then hardened. Next the optoelectronic layer 506 may be formed by transferring a liquid-phase organic optoelectronically active material to a surface of the electrode layer 502 of the component from a rotating roll having a direct contact with the surface of the electrode layer 502 moving along with the rotation of the rotating roll. The liquid-phase optoelectronic layer 506 is then hardened. Next the operational layer 504 may be formed by transferring a liquid-phase operational material to a surface of the optoelectronic layer 506 of the component from a rotating roll having a direct contact with the surface of the optoelectronic layer 506 moving along with the rotation of the rotating roll. The liquid-phase operational layer 504 is then hardened. Finally, the electrode layer 500 may be formed by transferring a liquid-phase electrode material to a surface of the operational layer 504 of the component from a rotating roll having a direct contact with the surface of the operational layer 504 moving along with the rotation of the rotating roll. Like the other layers, the liquid-phase electrode layer 500 is then hardened.

All other layers except the organic optoelectronically active layer 506 may also be deposited using some other method than gravure coating, such as spin coating, dip coating, vacuum thermal deposition or screen printing. A common anode material for the electrodes 502 and 500 is ITO (Indium-Tin-Oxide) sputtered onto glass or plastic substrate, but other choices are, for example, PEDOT:PSS (Poly(3,4-ethylenedioxythiophene):poly(styrene-sulfonate)), PANI-csa (polyaniline-camphorsulfonic acid) and Ppy-tsa (poly-pyrrole-p-toluenesulfonic acid) conductive polymers which can be used in gravure coating. Metal pastas including metals, such as gold, silver, copper, or carbon can also be printed with gravure coating. The demands for anode film are high transparency at visible region, small sheet resistance, high work function and low surface roughness.

A high purity substrate can be used to achieve a durable component. Cleaning can be performed with a common solvent such as isopropanol, ethanol and methanol. Furthermore, plasma treatment may be needed to smooth the film morphology, to increase the work function, and to remove residual particles.

In FIG. 5, the electrode layer 500 has a gap 510 which represents the possibility to pattern the layers of the component. Patterning and hardening of the at least one layer of a liquid-phase layer can be performed by using radiation or chemical treatment. Usually, electromagnetic radiation for hardening a layer is ultraviolet or X-ray radiation. Moreover, electron radiation may be used. An electrode of the component or at least one layer of the organic optoelectronically active material of the component can be patterned for forming a desired shape of the active region.

After depositing of the organic optoelectrically active material, with or without patterning, a low work function metal layer is deposited through a shadow mask on the layer of the organic optoelectrically active material. The shadow mask defines an active area seen from the cathode side of a component. A low work function is necessary to ensure efficient, low-resistance injection of electrons from the cathode into the electron transport layer. A deposited organic layer may be 5 nm to more than 100 nm thick and electrode layers may typically be over 100 nm thick (can also be thinner). The operation of the device is not as sensitive to the cathode thickness as to the organic layer thickness. A thick cathode can transport enough charges homogeneously to the full area of the component. A thick enough cathode can also be opaque, when emission is wanted in one direction only.

When a voltage is coupled from a power supply 512 to the electrodes 500, 502, the optoelectronic operation begins. When the component is a LED (Light Emitting Diode), it emits optical radiation on a wavelength depending on the composition of the organic optoelectronically active material. When the component is a diode detector, the amount of current that passes between the electrodes 500, 502 varies according to the optical radiation applied on the component, i.e. the component can be used to detect the radiation and the power of the radiation it receives. The area of the gap 510 has no optoelectronic function because no electric field can be applied to the optoelectronically active layer 506.

FIG. 6 shows a component which is similar to the component in FIG. 5 except that the organic optoelectronically active layer has been patterned. The gap in the pattern has been filled with an optoelectronically inactive and electrically isolating filling 600.

FIG. 7 shows a multilayer structure which comprises electrode layers 700 to 704. Each of the organic optoelectrically active layers 506 is in between at least one pair of electrode layers. Electrode layers 700 and 702, electrode layers 702 and 704 and electrode layers 700 and 704 can be considered to be pairs of electrode layers. In between the pair of electrode layers 702 and 702 there are two organic optoelectronically active layers. In general, any pair of electrode layers may have one or more layers of organic optoelectronically active material.

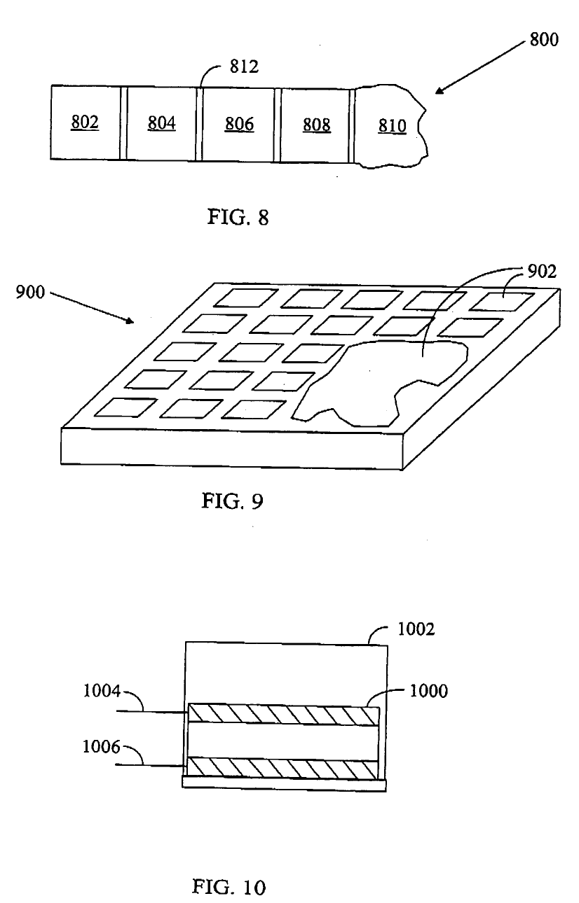

FIG. 8 presents an array 800 of components 802 to 810. At least one organic optoelectrically active layer of one component or the whole array of components may be formed using the gravure coating method. The components can be separated from each other with a boundary structure 812. The array may also be a multilayer structure. An element in the array may comprise one uniform layer of organic optoelectronically active material or a group of droplets of organic optoelectronically active material (see FIG. 2A and FIG. 2B).

FIG. 9 shows an example of a component having a matrix 900 of elements 902. At least one organic optoelectrically active layer of one element or the whole matrix of elements may be formed using the gravure coating method. The components can be separated from each other with a boundary structure (no reference number in FIG. 9) similar to that in FIG. 8. Each element may also be a single component which can be separated from another by cutting the substrate into pieces such that each piece includes a desired number of components. The matrix may also be a multilayer structure. The size and shape of each element in the component can be arbitrary. All elements can be emitting or absorbing, or some elements can be emitting and some elements absorbing. An element in the matrix may comprise one uniform layer of organic optoelectronically active material or a group of droplets of organic optoelectronically active material (see FIG. 2A and FIG. 2B).

All in all, one or more organic optoelectronically active layers may be deposited between electrodes. One of the electrodes needs to be at least partially transparent in order to observe optical emission from the organic layer. Usually an ITO-coated glass substrate is used as the anode. Semitransparent metal can also be used, although it tends to be less transmitting at thicknesses that are conductive enough for electrodes. Typically, one electrode is made of thick metal and it also works as a mirror reflecting optical radiation back towards the transparent electrode.

FIG. 10 illustrates encapsulation. Because the organic materials can be sensitive to oxygen and moisture, a component 1000 is usually encapsulated with, for example, a glass or metal lid 1002 having desiccant and an UV-cured epoxy sealant. The lid 1002 can be fixed to the substrate. Wires 1004 to 1006 coming out of the lid 1002 are coupled to the electrodes.

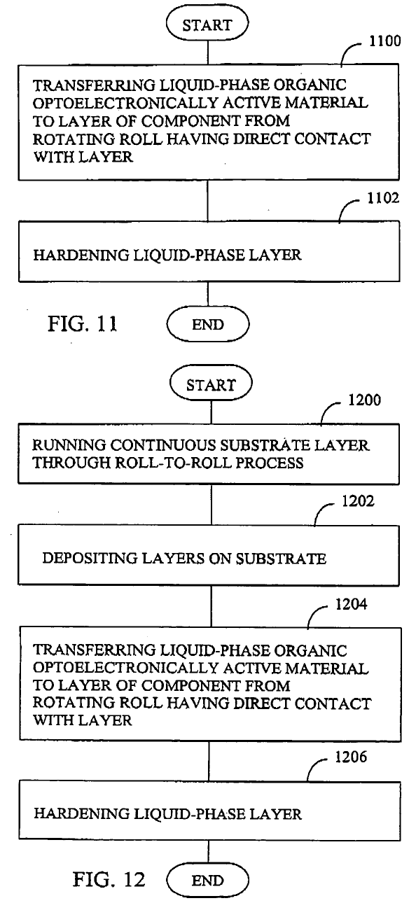

FIG. 11 illustrates a flow chart of the method for fabricating an optoelectronic component including layers such that the layers comprise at least two electrode layers for electric coupling and at least one organic optoelectronically active layer, each of which being placed between at least one pair of electrode layers. In step 1100, at least one organic optoelectronically active layer is formed by transferring a liquid-phase organic optoelectronically active material to a surface of a layer of the component from a rotating roll having a direct contact with the surface of the layer moving along with the rotation of the rotating roll. In step 1102, the liquid-phase layer is hardened.

FIG. 12 illustrates a flow chart of the method for fabricating at least one optoelectronic component. Each component includes layers, which comprise at least two electrode layers for electric coupling and at least one organic optoelectronically active layer each of which being placed between a pair of electrode layers. In step 1200, a continuous substrate layer is run through a roll-to-roll process using rotating rolls. In step 1202, other layers of the at least one component are deposited on the substrate layer. In step 1204, at least one organic optoelectronically active layer is formed according to a gravure coating method in the roll-to-roll process by transferring a liquid-phase organic optoelectronically active material to a surface of a layer from a rotating roll having a direct contact with the surface of the layer. In step, 1206 the liquid-phase layer is hardened.

The OLED has advantages when used in a flat panel display. The panel may be thin and light. The panel may have a low operational voltage, low power consumption, emissive source, good daylight visibility with high brightness and contrast, high resolution, fast switching, broad colour gamut and a wide viewing angle. Furthermore, by using a gravure coating method no special fabrication processes (e.g. the vacuum evaporators) and rooms (e.g. clean room environment) are necessarily needed.

Plastic substrates have also advantages. Polymer materials are lighter than glass. The use of a plastic substrate can significantly reduce the weight and thickness. Polymers are not brittle but yet durable. Polymers are bendable, and hence, a plastic material can conform, bend or roll into any shape. In other words, plastic displays may be laminated onto non-flat surfaces. Plastic displays may be more economic in mass production than most glass-based counterparts. Moreover, polymer foil is easy to handle.

The optoelectronical component having detection principle may be used to generate electricity from optical radiation since the component can transform optical power into electric power which, in turn, can be supplied to the optoelectronical component transmitting optical radiation.

The component can be applied, for example, to large displays and to illumination (illuminating curtains or wall papers). The component can also have a use in cartons and cans for various products such that a flexible display on a container can present colourful flashing lights or moving pictures to make a consumer to buy the product. Clothes, for example, of rescue workers, police or road repair workers could also be provided with flexible warning lights. Additionally, adhesive labels, newspapers, magazines, advertisements etc. could be useful applications of the component.

Even though the invention has been described above with reference to examples according to the accompanying drawings, it is clear that the invention is not restricted thereto but can be modified in several ways within the scope of the appended claims.

1. A method of fabricating an optoelectronic component including layers, the layers comprising at least two electrode layers for electric coupling and at least one organic optoelectronically active layer, each of the at least one organic optoelectronically active layer being placed between at least one pair of electrode layers, the method comprising
forming at least one organic optoelectronically active layer by transferring a liquid-phase organic optoelectronically active material onto a surface of a layer of the component from a rotating roll having a direct contact with the surface of the layer moving along with rotation of the rotating roll.

2. A method for fabricating at least one optoelectronic component, each component including layers, the layers comprising at least two electrode layers for electric coupling and at least one organic optoelectronically active layer, each of the at least one organic optoelectronically active layer being placed between a pair of electrode layers, the method comprising
running a continuous substrate layer through a roll-to-roll process using rotating rolls,
depositing other layers of the at least one component on the substrate layer; and
forming, according to a gravure coating method, at least one organic optoelectronically active layer in the roll-to-roll process by transferring a liquid-phase organic optoelectronically active material onto a surface of a layer from a rotating roll having a direct contact with the surface of the layer.

3. The method of claim 1, the method further comprising transferring the organic optoelectronically active material onto a surface of an electrode layer of a pair of electrodes from a roll having a direct contact with the surface of the electrode layer.

4. The method of claim 1, the method further comprising
forming a structure of at least one operational layer between at least one pair of electrode layers;
transferring the organic optoelectronically active material onto a surface of the structure of at least one operational layer from a roll having a direct contact with the surface of the structure of at least one operational layer.

5. The method of claim 2, the method further comprising forming more than one component and separating the components by cutting the continuous substrate having components into pieces including a desired number of components.

6. The method of claim 1, the method further comprising depositing all layers of the at least one component except the substrate layer one after another; and
depositing each layer by transferring the liquid-phase component material onto a surface of a layer of the component from a rotating roll having a direct contact with the surface of the layer moving along with the rotation of the rotating roll.

7. The method of claim 2, the method further comprising forming an array or a matrix of components.

8. The method of claim 1, the method further comprising forming a multilayer component by depositing layers of at least two components one upon another.

9. The method of claim 2, the method further comprising forming, using a substrate, a layer of the at least one component.

10. The method of claim 1, the method further comprising hardening the at least one organic optoelectronically active layer of liquid-phase using radiation or chemical treatment.

11. The method of claim 1, the method further comprising spreading the liquid-phase organic optoelectronically active material to the rotating roll having the direct contact with the surface of the layer of the component.

12. The method of claim 1, the method further comprising
spreading the liquid-phase organic optoelectronically active material to a first rotating roll;
transferring the liquid-phase organic optoelectronically active material from the first roll to a second rotating roll; and
forming at least one organic optoelectronically active layer by transferring the liquid-phase organic optoelectronically active material onto a surface of a layer of the component from the second rotating roll having a direct contact with the surface of the layer moving along with the rotation of the rotating rotating roll.

13. The method of claim 1, the method further comprising transferring droplets of the liquid-phase organic optoelectronically active material to the surface of the layer of the component from cells of the rotating roll having a direct contact with the surface of the layer, such liquid-phase droplets remaining separately onto the surface on which they have been transferred.

14. The method of claim 13, the method further comprising forming components having a size of a droplet.

15. The method of claim 1, the method further comprising transferring droplets of the liquid-phase organic optoelectronically active material onto the surface of the layer of the component from cells of the rotating roll having a direct contact with the surface of the layer, such liquid-phase droplets joining together, forming a uniform layer on the surface onto which they have been transferred.

16. The method of claim 1, the method further comprising patterning an electrode of the component for forming a desired shape of the active region.

17. The method of claim 1, the method further comprising patterning at least one layer of the organic optoelectronically active material of the component for forming a desired shape of the active region.

18. The method of claim 1, the method further comprising encapsulating the component.

19. An optoelectronic component including layers, the layers comprising at least two electrode layers for electric coupling and at least one organic optoelectronically active layer, each of the at least one organic optoelectronically active layer being placed between at least one pair of electrode layers, and
the at least one organic optoelectronically active layer of the optoelectronic component being formed by transfer of a liquid-phase organic optoelectronically active material onto a surface of a layer of the component from a rotating roll having a direct contact with the surface of the layer moving along with rotation of the rotating roll.

20. An optoelectronic component including layers, the layers comprising at least two electrode layers for electric coupling and at least one organic optoelectronically active layer, each of the at least one organic optoelectronically active layer being placed between at least one pair of electrode layers, and
the at least one organic optoelectronically active layer of the optoelectronic component being formed using a gravure coating method with transfer of a liquid-phase organic optoelectronically active material onto a surface of a layer of the component from a rotating roll having a direct contact with the surface of the layer in a roll-to-roll process where a continuous substrate layer is run through the process using rotating rolls.
